(19) United States
(12) Patent Application Publication
(10) Pub. No.: US 2012/0118378 A1
(43) Pub. Date: May 17, 2012

(54) Non-Linear Solar Receiver

(76) Inventor: Michael Gurin, Glenview, IL (US)

(21) Appl. No.: 13/295,397

(22) Filed: Nov. 14, 2011

Related U.S. Application Data
(60) Provisional application No. 61/414,379, filed on Nov. 16, 2010.

(51) Int. Cl. F24J 2/24; H01L 31/024; F24J 2/30

(52) U.S. Cl. 136/259; 126/643; 126/663

(57) ABSTRACT

The present invention generally relates to non-linear solar receivers particularly optimized for high temperature thermodynamic cycles. In one embodiment, the present invention relates to a non-linear solar receiver comprised of at least two heat exchangers with one first set of heat exchangers increasing the enthalpy in a relatively lower temperature to the one second set of heat exchangers increasing the enthalpy of either the thermodynamic cycle working fluid or a heat transfer fluid.

### FIELD OF THE INVENTION

The present invention generally relates to non-linear solar receivers that utilize at least one solar receiver having an integral microchannel heat exchanger. In one embodiment, the present invention relates to a non-linear solar receiver comprised of at least two heat exchangers wherein at least one of the heat exchangers absorbs solar energy to heat a working fluid at a relatively lower temperature, at least one of the heat exchangers absorbs solar energy to heat the same working fluid at a relatively higher temperature, and wherein the heat exchanger with the relatively higher temperature emits lower energy out of the solar receiver by reflecting emitted energy towards the at least one of the heat exchangers at the relatively lower temperature.

### BACKGROUND OF THE INVENTION

Due to a variety of factors including, but not limited to, global warming issues, fossil fuel availability and environmental impacts, crude oil price and availability issues, alternative energy sources are becoming more popular today. One such source of alternative and/or renewable energy is solar energy. One such way to collect solar energy is to use a solar receiver to focus and convert solar energy into a desired form (e.g., thermal energy or electrical energy). Given this, solar receivers that function in efficient manners are desirable. Traditional thermal activated power generation effectively considers every unit of energy into the power generation thermodynamic working fluid in equivalent terms to another at a given input temperature. This is also a consideration within the prevalent solar activated power generation systems most notably concentrated parabolic troughs and central tower receivers. This has resulted in the utilization, at least with indirect heating of a heat transfer fluid (e.g., Therminol tm), of a relatively small temperature differential between the heat transfer fluid inlet temperature and discharge temperature and also therefore at a high temperature. The high temperature of the heat transfer fluid, relative to the discharge temperature, is counter to the solar optical efficiency as emissivity increases significantly at increasing temperatures. Furthermore, the ability to reach the high discharge temperature in order to maximize Carnot efficiency of the thermodynamic cycle requires high concentration and active solar tracking that are significantly more expensive than non-tracking solar collectors.

### SUMMARY OF THE INVENTION

The present invention generally relates to non-linear solar receivers that utilize at least one solar receiver with an integral heat exchanger having the portion of the solar receiver having the highest emitted energy not reflecting back into another portion of the solar receiver passing the relatively lower temperature heat transfer fluid to the discharged higher temperature heat transfer fluid. In one embodiment, the present invention relates to a non-linear solar receiver comprised of at least two heat fluid passes within the at least one heat exchanger.

In one embodiment, the present invention relates to a non-linear solar receiver comprising: at least one heat exchanger, wherein the at least one heat exchanger has an integral microchannel heat exchanger; and the at least one heat exchanger provides an approximately equivalent solar absorption rate with the heat transfer rate to a working fluid across the surface area of the non-linear solar receiver.

In still another embodiment, the present invention relates to a non-linear solar receiver comprising: at least one heat exchanger, wherein the at least one heat exchanger has at least two distinct zones having different solar absorption and emissivity; and one of the two at least distinct zones has an increasing emissivity for the distinct zone optically furthest away from the sun.

In still another embodiment, the present invention relates to a non-linear solar receiver comprising: at least one heat exchanger, wherein the at least one heat exchanger has an integral microchannel heat exchanger; and the at least one heat exchanger provides an approximately equal solar absorption rate with the heat transfer rate to a working fluid.

In still another embodiment, the present invention relates to a non-linear solar receiver that utilizes at least one integral heat exchanger having the portion of the solar receiver having the highest emitted energy not reflecting back into another portion of the solar receiver passing the relatively lower temperature heat transfer fluid to the discharged higher temperature heat transfer fluid.

In one embodiment, the present invention relates to a non-linear solar receiver comprised of at least two heat fluid passes within the at least one heat exchanger.

In still another embodiment, the present invention relates to a non-linear solar receiver having an integral heat exchanger comprised of at least two heat fluid passes within the integral heat exchanger, wherein at least one of the two heat fluid passes is operable as the fluid boiler, and wherein at least one of the two heat fluid passes is operable as the fluid superheater.

In still another embodiment, the present invention relates to a non-linear solar receiver comprising: at least one integral heat exchanger; at least one reflector; and at least one actuator to vary the capture of solar energy into the solar receiver operable to prevent disassociation of heat transfer fluid.

In still another embodiment, the present invention relates to non-linear solar receivers as shown and described herein.

### BRIEF DESCRIPTION OF THE DRAWINGS

FIG. 1 is a cross-sectional illustration of one embodiment of a non-linear solar receiver having multiple passes in accordance with the present invention;

FIG. 2 is a cross-sectional illustration of another embodiment of a non-linear solar receiver having multiple passes in accordance with the present invention;

FIG. 3 is a cross-sectional illustration of another embodiment of a non-linear solar receiver having multiple passes in accordance with the present invention;

FIG. 4 is a cross-sectional illustration of another embodiment of a non-linear solar receiver having multiple passes in accordance with the present invention;

FIG. 5 is a cross-sectional illustration of another embodiment of a non-linear solar receiver having a single fluid cavity in accordance with the present invention;

FIG. 6 is a cross-sectional illustration of another embodiment of a non-linear solar receiver having at least two fluid inlets closer to at least one fluid discharge relative to a solar concentrator in accordance with the present invention;

FIG. 7 is a cross-sectional illustration of another embodiment of a non-linear solar receiver having at least one fluid inlet and at least one fluid discharge with a heat exchanger integral to the solar receiver in accordance with the present invention;

FIG. 8 is a cross-sectional illustration of another embodiment of a non-linear solar receiver having at least one fluid inlet and at least one fluid discharge with a heat exchanger integral to the solar receiver in accordance with the present invention;

FIG. 9 is a cross-sectional illustration of another embodiment of a non-linear solar receiver having fluid inlet in a microporous layer closest to the solar concentrator in accordance with the present invention;

FIG. 10 is a cross-sectional illustration of another embodiment of a non-linear solar receiver having fluid inlet in a porous foam layer closest to the solar concentrator and subsequent layers having increasing porosity in accordance with the present invention;

FIG. 11 is a cross-sectional illustration of one embodiment of a non-linear solar receiver having multiple distinct coating zones of absorption and emissivity levels in accordance with the present invention;

FIG. 12 is a cross-sectional illustration of another embodiment of a non-linear solar receiver having multiple distinct coating zones of absorption and emissivity levels, and a distinct zone void of coatings in accordance with the present invention;

FIG. 13 is a cross-sectional illustration of another embodiment of a non-linear solar receiver having multiple passes in accordance with the present invention;

FIG. 14 is a cross-sectional illustration of another embodiment of a non-linear solar receiver having multiple passes with at least one pass serving a fluid boiler and at least one pass serving a fluid superheater in accordance with the present invention;

FIG. 15 is a cross-sectional illustration of another embodiment of a non-linear solar receiver having multiple passes in accordance with the present invention;

FIG. 16 is a cross-sectional illustration of another embodiment of a non-linear solar receiver having at least two passes with sequential passes of the same heat transfer fluid.

FIG. 17 is a sequential flow diagram depicting a sequential pass within a solar receiver interspersed by fluid to fluid heat exchanger.

FIG. 18 is a series of graphs showing the thermodynamic properties of water as a function of temperature at an operating pressure of 4000 psia.

FIG. 19 is a series of graphs showing the thermodynamic properties of carbon dioxide as a function of temperature at an operating pressure of 2700 psia.

FIG. 20 is a cross-sectional illustration of another embodiment of a non-linear solar receiver having at least two passes with sequential passes of the same heat transfer fluid as concentric cylinders.

FIG. 21 is a cross-sectional illustration of a first embodiment of a non-linear solar receiver having radiant energy from both the sun and a radiant burner.

FIG. 22 is a cross-sectional illustration of a second embodiment of a non-linear solar receiver having radiant energy from both the sun and a radiant burner.

FIG. 23 are three embodiments of a solar receiver in a tower configuration.

### DETAILED DESCRIPTION OF THE INVENTION

The term “non-linear”, as used herein, includes any surface of a solar receiver whose surface shape is described by a set of nonlinear equations.

The term “microchannel”, as used herein, includes channel dimensions of less than 2 millimeter.

The term “high surface area foam”, as used herein, includes foams having an open cell porosity greater than 50%.

The term “micropores”, as used herein, includes pores within a high surface area foam foams.

The term “thermal barrier coating” or “TBC”, as used herein, includes thermally insulative coatings that can sustain an appreciable temperature difference between the hot side of and cold side on which the coating is applied.

The term “reflector”, as used herein, includes a surface or surface coating that reflects greater than 50% of at least one portion of the incoming light spectrum, which includes the portions of visible, infrared, and ultraviolet.

The term “in thermal continuity” or “thermal communication”, as used herein, includes the direct connection between the heat source and the heat sink whether or not a thermal interface material is used.

The term “multipass”, “multi-pass”, or “multiple passes”, as used herein, includes a fluid flow into at least one portion of a heat exchanger and out of at least one other portion of a heat exchanger wherein the at least one portion of the heat exchanger and the at least one other portion of a heat exchanger can either be thermally isolated from each other or in thermal continuity with each other.

The term “fluid inlet” or “fluid inlet header”, as used herein, includes the portion of a heat exchanger where the fluid flows into the heat exchanger.

The term “fluid discharge”, as used herein, includes the portion of a heat exchanger where the fluid exits the heat exchanger.

The term “heat spreader”, as used herein, includes a heat sink having the ability to extend the surface area of heat transfer.

The term “lowest emissivity”, as used herein, includes a portion of a solar receiver surface having a lower specific emissivity level at the specific surface temperature for that portion of the solar receiver as compared to at least 80% of the other portions of the solar receiver.

The term “highest absorption”, as used herein, includes a portion of a solar receiver surface having a higher specific absorption level at the specific surface temperature for that portion of the solar receiver as compared to at least 80% of the other portions of the solar receiver.

The term “boiler”, as used herein, includes a heat exchanger transferring thermal energy into a working fluid wherein the working fluid is comprised of at least 5% vapor phase.

The term “superheater”, as used herein, includes a heat exchanger transferring thermal energy into a working fluid wherein the heat exchanger is used to convert saturated steam into dry steam.

The term “motion actuator”, as used herein, includes a device capable of changing the position of a connected device such as a reflector from one position to another position.

The term “diffuser”, as used herein, includes a device that diffuses or spreads out or scatters light in some manner. One such exemplary device is WhiteOptics™.

The term “photovoltaic cell” or “PV” or “PV cell”, as used herein, includes an energy device that is capable of converting photons into electrons or excited electrons “excitons”.

The present invention generally relates to non-linear solar receivers that utilize at least one solar receiver having a non-linear shape having at least one integral heat exchanger, and a solar concentrator that focuses solar energy on the non-linear solar receiver.

In one embodiment, the present invention relates to a non-linear solar receiver comprised of a multiple pass heat exchanger. The multiple pass heat exchanger is comprised of at least two distinct heat exchanger circuits operable to increase the temperature of the working fluid passing through the solar receiver. In one instance, the solar receiver side not facing the solar energy “non-facing side” has a thermal barrier coating. A particularly preferred thermal barrier coating has an emissivity lower than 10%, and a specifically preferred thermal barrier coating has an emissivity lower than 5%. In another instance, the solar receiver has an internal reflector to reflect incoming solar energy further into the depths of the internal cavity containing the subsequent (i.e., not the first pass) pass heat exchanger for further heating of the working fluid. In yet another instance, the first pass heat exchanger is facing the direction of the incoming solar energy and at least the second pass heat exchanger is on the non-facing side.

In yet another embodiment, the present invention relates to a non-linear solar receiver comprised of at least one fluid inlet header and at least one fluid discharge wherein the fluid enters the fluid inlet header, flows through the cross section of the integral heat exchanger (i.e., not through the length of the solar receiver), and exits through the fluid discharge port. In one instance, the fluid inlet header is in the portion of the non-linear solar receiver where emitted energy would not reflect onto another portion of the non-linear solar receiver. This instance is configured to be operable as a means to reduce the emitted energy losses by having the portion of the solar receiver most susceptible to emissivity losses having the lowest surface temperature (i.e., lowest incoming working fluid temperature), wherein it is recognized in the art that emissivity increases as coating temperature increases. In one instance the first pass heat exchanger is in thermal continuity with the second pass heat exchanger. In another instance the first pass heat exchanger is not in thermal continuity with the second pass heat exchanger.

In another embodiment, the present invention relates to a non-linear solar receiver comprised of at least one fluid inlet header, at least one fluid discharge port, and at least two layers forming an integral heat exchanger. The first layer of the at least two layers is facing the incoming solar flux and comprises micropores. The second layer of the at least two layers is on the non-facing side of the first layer. In one instance the second layer has an increasing pore size as compared to the first layer by at least 10% operable to increase the surface area as a means to increase heat transfer to the working fluid despite the lower thermal conductivity and decreased fluid density as the working fluid temperature rises. In another instance, a third layer is on the non-facing side of the second layer and has a further increasing pore size by at least 10% over the second layer pore size. In yet another instance, the first layer is a sintered metal as a means of increasing heat transfer into the working fluid.

In yet another embodiment, the present invention relates to a non-linear solar receiver comprised of at least two portions wherein the first of the at least two portions is closer to the fluid inlet header and has the lowest emissivity value within the receiver solar flux facing side, and wherein the second of the at least two portions further away from the fluid inlet header and closer to the fluid discharge port has the highest absorption value within the receiver. In one instance, the non-linear solar receiver has a portion that is void of a solar absorption coating. The portion void of a solar absorption coating is closest to the fluid discharge port and preferably within the interior depths of the internal cavity created by the non-linear solar receiver shape. This is operable as a means of reducing the ability of a solar absorption coating from deteriorating due to the maximum temperatures of the working fluid.

In one embodiment, the present invention relates to a non-linear solar receiver comprised of at least two passes heat exchanger for working fluid heat transfer operable as a means to increase the approximate equivalence of solar flux and heat transfer. In one instance a third pass heat exchanger is in thermal continuity with the non-facing side of the second pass heat exchanger operable as a means to overcome the deteriorated heat transfer into the working fluid (potentially attributed to phase change into vapor). In another instance the first pass heat exchanger is operable as a boiler, and the second pass heat exchanger is operable as a superheater.

In yet another embodiment, the present invention relates to a non-linear solar receiver comprised of at least one photovoltaic cell, at least one heat exchanger wherein the at least one heat exchanger provides active cooling of the photovoltaic cell. In one instance a second heat exchanger absorbs solar flux to further heat the heat transfer fluid to provide thermal energy to drive at least one thermodynamic cycle. The first heat exchanger is operable as a first pass heat exchanger, and the second heat exchanger is operable as a second pass heat exchanger. A particularly preferred embodiment is whereby the heat transfer fluid changes phase within the first pass heat exchanger.

In another embodiment, the present invention relates to a solar receiver comprised of at least two passes heat exchanger with the same heat transfer fluid passing sequentially through the at least two passes heat exchanger. In one instance the first pass heat exchanger takes the heat transfer fluid from the lower portion of the heat transfer rate curve to within plus or minus 10 C of the inflection point of the heat transfer rate curve. A particularly preferred embodiment is whereby the deviation from linearity around the inflection point has heat transfer into the thermodynamic working fluid through a fluid-to-fluid heat exchanger or a solar receiver heat pipe/thermosiphon as method to avoid solar hot spots.

Here, as well as elsewhere in the specification and claims, individual numerical values and/or individual range limits can be combined to form non-disclosed ranges.

In another embodiment, the heat exchanger is a microchannel heat exchanger or high surface area foam in thermal continuity with the heat transfer fluid pipe operable as a heat spreader to achieve an increase in heat spreader surface area of greater than about 20%, greater than about 50%, greater than about 100%, or even greater than about 500% on the at least first heat exchanger or second heat exchanger.

The heat transfer fluid within the embodiments is preferably a supercritical fluid as a means to reduce the pressure drop within the heat exchanger. The supercritical fluid includes fluids selected from the group of organic refrigerants (R134, R245, pentane, butane), gases (CO2, H2O, He2), The specifically preferred supercritical fluid is void of hydrogen as a means to virtually eliminate hydrogen reduction or hydrogen embrittlement on the heat exchanger coatings or substrate respectively. The particularly preferred supercritical fluid has a disassociation rate less than 0.5% at the operating temperature in which the heat exchanger operates. The specifically preferred heat transfer fluid is the same working fluid within a thermodynamic cycle operable within a power generating cycle, vapor compression cycle, heat pump cycle, absorption heat pump cycle, or thermochemical heat pump cycle.

All of the embodiments can be further comprised of a control system operable to regulate the mass flow rate of the working fluid into the solar receiver, with the ability to regulate the mass flow rate independently for each pass by incorporating a fluid tank having variable fluid levels optionally interspersed between at least one pass and the other. One method of control includes a working fluid inventory management system. The control system regulates the mass flow rate through methods known in the art including variable speed pump, variable volume valve, bypass valves, and fluid accumulators. The control system is further comprised of at least one temperature sensor for fluid discharge temperature and at least one temperature sensor for ambient air temperature or condenser discharge temperature.

Exemplary embodiments of the present invention will now be discussed with reference to the attached Figures. Such embodiments are merely exemplary in nature and not to be construed as limiting the scope of the present invention in any manner. The depiction of heat exchangers predominantly as microchannel heat exchangers having linear porting is merely exemplary in nature and can be substituted by complex shaped porting of microchannel dimensions or porting greater than defined by microchannel practice. The utilization of a solar coating, as known in the art, is assumed as an optional feature within any portion of the non-linear solar receiver even though it may not be explicitly shown. With regard to FIGS. 1 through 22, like reference numerals refer to like parts.

Turning to FIG. 1, FIG. 1 is a cross-sectional illustration of one embodiment of a non-linear solar receiver in accordance with the present invention. In the embodiment of FIG. 1 non-linear solar receiver is comprised of a first pass microchannel heat exchanger “Pass 1” 10, a second pass microchannel heat exchanger “Pass 2” 15, and another microchannel heat exchanger operating either in sequence of the Pass 1 heat exchanger or the Pass 2 heat exchanger “Pass 2|3” 20 which collectively forms the non-linear solar receiver. The non-linear solar receiver can be designed to be any desired shape. As such, the present invention is not limited to any one geometric shape, with the preferred embodiment being a non-linear shape achieving the highest effective solar absorption and the lowest solar emissivity. The shape can be a series of linear extruded microchannel heat exchangers (or even traditional heat exchangers having port dimensions greater than the 2000 micron diameter typically classified as microchannel) assembled in a configuration to maximize emitted energy through surface emissivity reflected onto a heat exchanger having a lower fluid temperature.

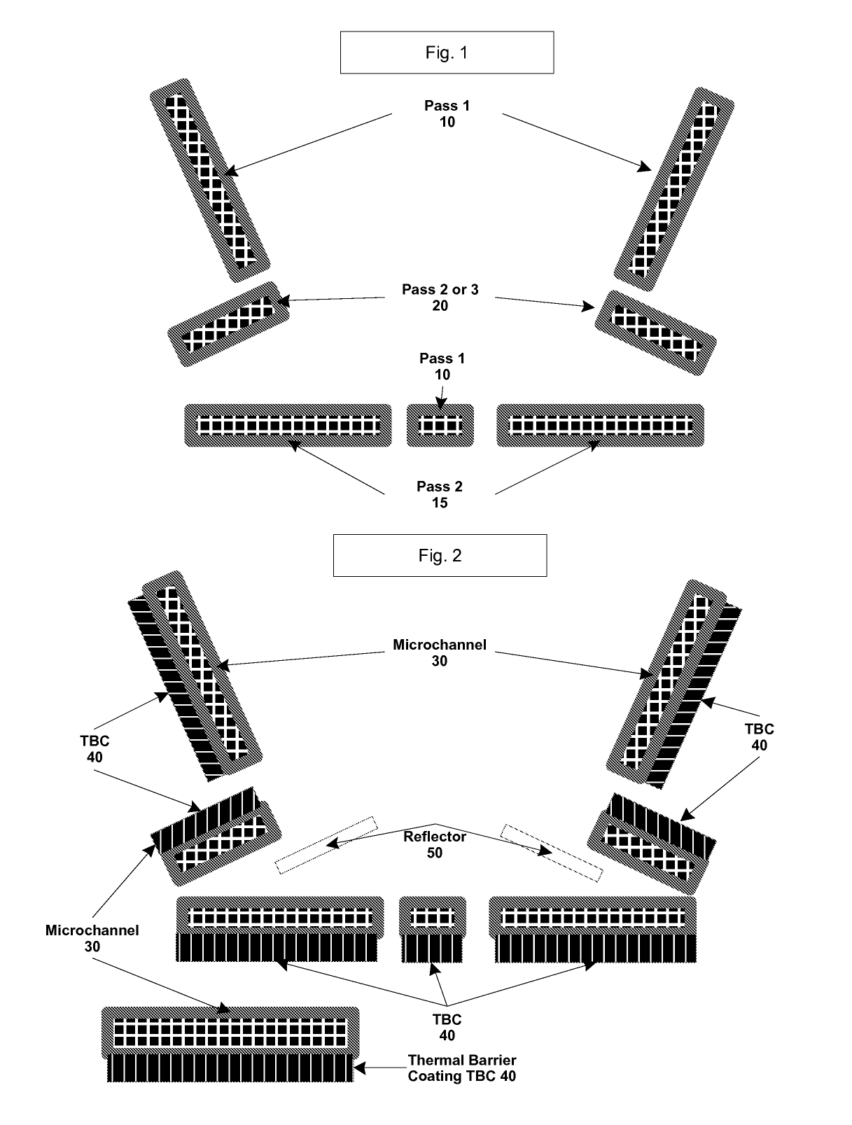

Turning to FIG. 2, FIG. 2 depicts additional components including a thermal barrier coating “TBC” 40 on the general sequential pass microchannel heat exchangers 30. Thermal barrier coating is formed from any suitable thermally insulating material or thermal barrier material. Such materials are known to those of skill in the art and as such, a detailed discussion herein is omitted for the sake of brevity. The thermal barrier coating 40 has the role of lowering heat losses on the non-solar facing side of the microchannel heat exchangers 30. The non-linear solar receiver is optionally further comprised of two reflectors 50. The reflectors 50 can be designed to be any desired shape having the objective of minimizing the reflections of solar energy out of the non-linear solar receiver. The Reflectors 50 have a reflective surface formed from any suitable reflect material. Such materials include, but are not limited to, metal reflective layers, polymer reflective layers, metalized polymer films, or a combination thereof. Turning to FIG. 3, FIG. 3 depicts a two pass non-linear solar receiver comprised of a “Pass 1” 10 microchannel heat exchanger being the first surface on which solar flux impacts. The shape of microchannel heat exchanger “Pass 1” 10 is designed such that emitted energy is subsequently reflected onto the second pass “Pass 2” 15 microchannel heat exchanger. The shape of “Pass 2” 15 is optimally a non-linear shape such that emitted energy from “Pass 2” 15 is emitted onto either the non-solar facing side of “Pass 1” 10 or another portion of “Pass 2” 15 for effectively a second opportunity to capture the solar energy otherwise lost due to emissivity of the solar coating.

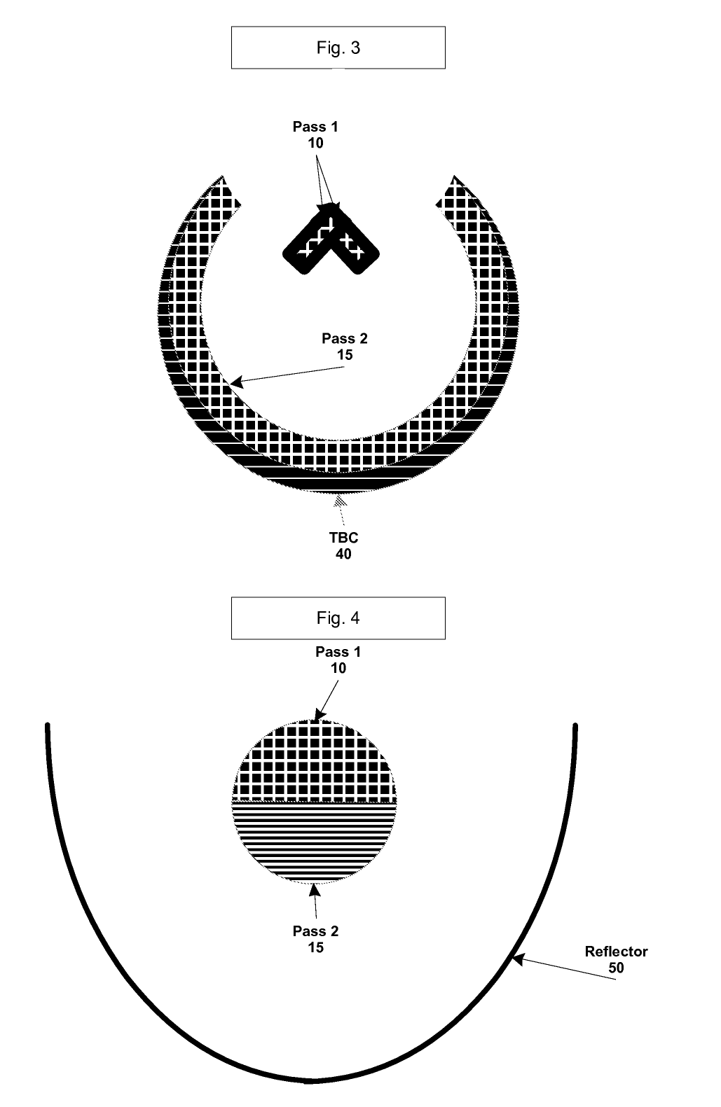

Turning to FIG. 4, FIG. 4 depicts a two pass solar receiver comprised of a single extrusion having effectively a solar facing “Pass 1” 10 and a non-solar facing “Pass 2” 15 heat exchanger. The shape of the heat exchanger can be any shape desired, and the solar facing “Pass 1” 10 and non-solar facing “Pass 2” 15 can be either a single extrusion with the two passes in thermal continuity or alternatively being thermally isolated from each pass. The further addition of a Reflector 50 enables the emitted energy from the higher temperature “Pass 2” 15 to have a second opportunity of being absorbed by another portion of the “Pass 2” heat exchanger.

Turning to FIG. 5, FIG. 5 depicts a single pass solar receiver having only one Fluid Cavity 70 in which heat transfer fluid gains thermal energy through solar absorption. The solar receiver is comprised of a receiver substrate and absorber coating 60 on the solar facing side, and a thermal barrier coating “TBC” 40 on the non-solar facing side. The shape of the receiver substrate 60 is non-linear with the objective of maximizing a second and potentially even a third reflection of emitted energy onto the receiver substrate.

Turning to FIG. 6, FIG. 6 depicts a non-linear solar receiver cross section having a fluid flow between the Fluid Inlet Headers 80 and the Fluid Discharge header 90, as differentiated from the prior figures having fluid flow in horizontal direction in relationship to the sun. This embodiment enables the portion of the non-linear solar receiver having limited opportunity for its emitted energy to be reflected onto another portion of the solar receiver to have a lower emitted amount of energy per square inch of surface area by ensuring that the temperature at that portion is lower than at the portion closest to the fluid discharge header 90. The objective of the shape, which can take any desired shape, is to maximize the opportunity for emitted energy to reflect onto another portion of the solar receiver.

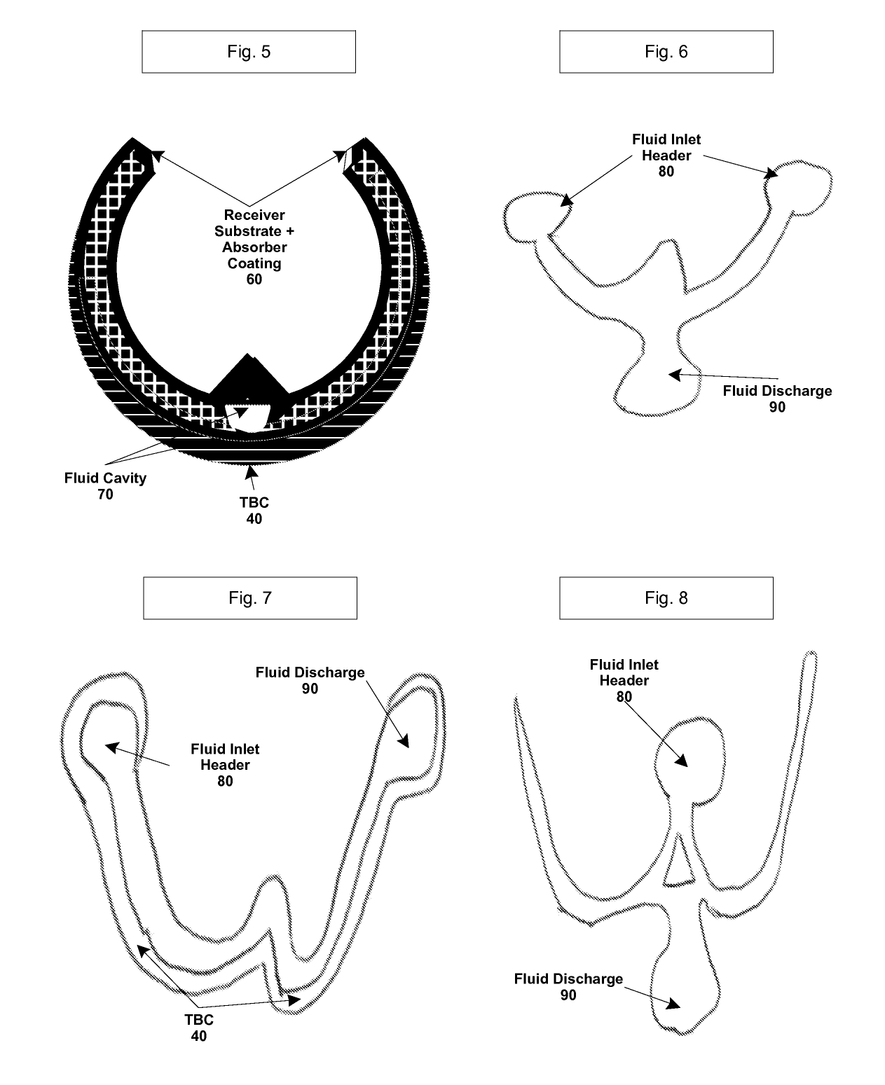

Turning to FIG. 7, FIG. 7 depicts a non-linear solar receiver cross section having a fluid flow between the Fluid Inlet Header 80 and the Fluid Discharge header 90. The fluid flow temperature gradient is not symmetric as per FIG. 6 therefore the shape of the non-linear solar receiver is also not symmetric. The shape of the non-linear solar receiver and the flow channel path within the non-linear solar receiver is optimally designed to match heat transfer rate at the surface into the heat transfer fluid with the solar flux on the non-linear solar receiver. The asymmetric design of the non-linear solar receiver enables the solar concentrator, which is not depicted, to also be asymmetric. An asymmetric concentrator enables the combined concentrator and receiver to experience lower wind load forces that contributes to a lower structural costs and associated installation costs. As such, a detailed discussion herein is omitted for the sake of brevity.

Turning to FIG. 8, FIG. 8 depicts a non-linear solar receiver cross section having a fluid flow between the Fluid Inlet Header 80 and the Fluid Discharge header 90 where the highest rate of solar flux falls on the Fluid Inlet Header 80. The shape of the non-linear solar receiver and the flow channel path within the non-linear solar receiver is optimally designed to match heat transfer rate at the surface into the heat transfer fluid with the solar flux on the non-linear solar receiver, and to minimize the surface temperature of the portion of the non-linear solar receiver having the lowest opportunit for emitted energy to be reflected onto another portion of the non-linear solar receiver.

Turning to FIG. 9, FIG. 9 depicts a solar receiver comprised of two layers, a sun facing layer Layer 1 95 having micropores and a non-sun facing Layer 2 100. The relatively cooler fluid flow enters the Fluid Inlet header 80 and leaves the Fluid Discharge header 90 for the objective of minimizing emitted energy losses by minimizing the temperature differential (i.e., hot spots) across the sun-facing side of the solar receiver surface. Emissivity, which is a function of surface temperatures, is highly non-linear thus a solar receiver having a small temperature differential has lower energy losses than a solar receiver having either hot spots or a single fluid inlet port and a single fluid discharge port as is typically the case with flat panel solar receivers having the heat transfer fluid contained within a copper tube often welded to the solar receiver coating substrate.

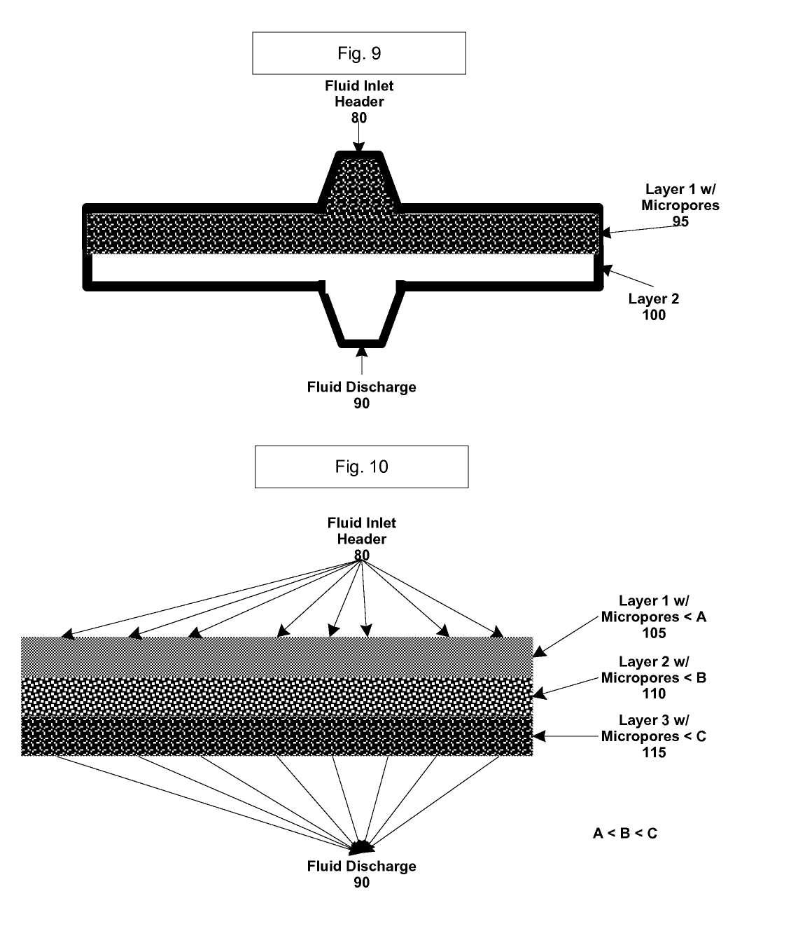

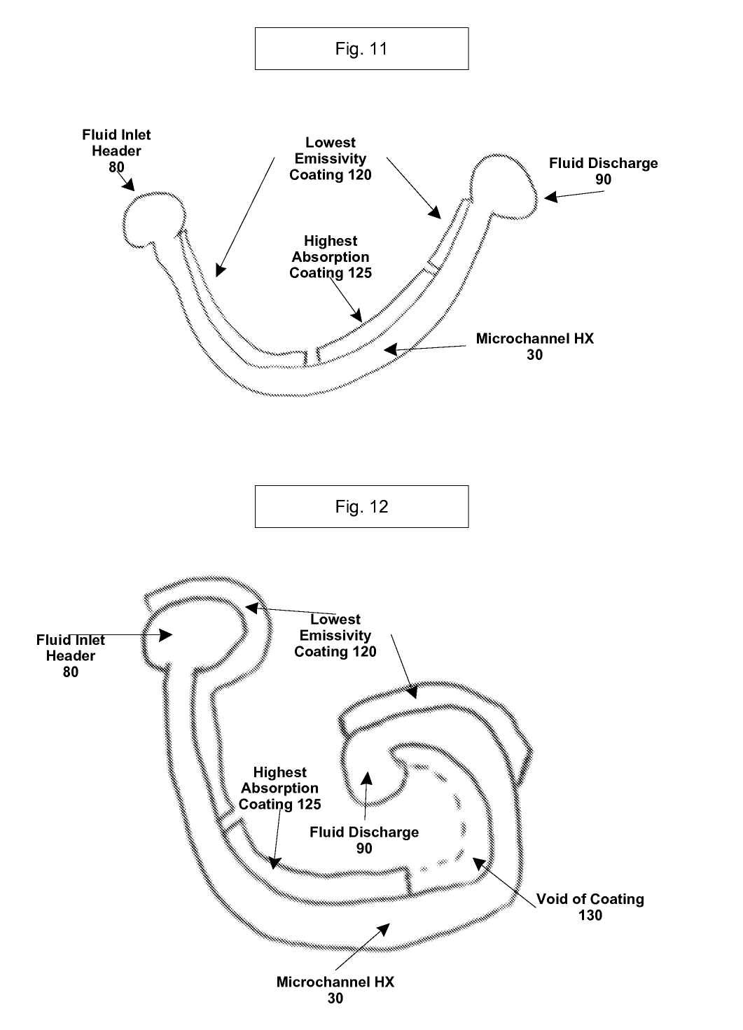

Turning to FIG. 10, FIG. 10 depicts another embodiment similar to FIG. 9. The solar receiver still has a Fluid Inlet header 80 and a Fluid Discharge header 90 having at least three layers, with three layers being shown, a Layer 1 105, a Layer 2 110, and a Layer 3 115. Each layer is a porous foam having a pore size for Layer 1, Layer 2, and Layer 3 respectively of A, B, and C where the pore size is increasing A<B<C as a method of increasing heat transfer rate as the working fluid within the solar receiver to offset the decreasing density and often decreasing thermal conductivity as the working fluid's temperature increases. This is particularly important at critical phase change temperatures, and more particularly important for phase changes from liquid to vapor of non-supercritical fluids. One embodiment of the solar receiver is Layer 1 105 being comprised of a sintered metal to enable the solar receiver to operate similar to a heat pipe.

Turning to FIG. 11, FIG. 11 depicts a cross section of another embodiment of the invention similar in nature to FIG. 7. The working fluid enters the Fluid Inlet 80 and exits the Fluid Discharge 90 through the integrated microchannel heat exchanger 30. The surface temperature of the non-linear solar receiver will vary from relatively cold to hot as the fluid travels from the Fluid Inlet 80 to the Fluid Discharge 90. As noted earlier, emissivity is a function of temperature. One configuration of a non-linear solar receiver has regions within the non-linear solar receiver having at least two different solar coatings with one exemplary being a Lowest Emissivity Coating 120 at the regions of the non-linear solar receiver least able to benefit from secondary reflections of emitted energy, and the Highest Absorption coating 125 at the regions of the non-linear solar receiver most able to benefit from secondary (at least, could be tertiary or higher).

Turning to FIG. 12, FIG. 12 also depicts a cross section of a derivative of FIG. 11. The shape of the non-linear receiver, which can be designed to be any desired optimal shape including multifunctional purposes. Again as in FIG. 11, The working fluid enters the Fluid Inlet 80 and exits the Fluid Discharge 90 through the integrated microchannel heat exchanger 30. The surface temperature of the non-linear solar receiver will vary from relatively cold to hot as the fluid travels from the Fluid Inlet 80 to the Fluid Discharge 90. FIG. 12 adds a region Void of Coating 130, preferably located in the region having the highest temperature within the non-linear solar receiver. A region Void of Coating 130 will take on the solar absorption and emissivity properties of the non-linear solar receiver substrate material, which may have inferior solar absorption and emissivity properties. However due to the fact that the reflected solar light will reflect deeper into the non-linear solar receiver this solar energy is not lost. Furthermore, the non-linear solar receiver will not experience coating degradation due to high temperatures, as known in the art by avoiding any surface coatings through the region Void of Coating 130.

Turning to FIG. 13, FIG. 13 depicts a cross section of another embodiment of the non-linear solar receiver. This embodiment depicts a multiple pass microchannel heat exchanger integral to the non-linear solar receiver. Each pass is sequential in terms of fluid flow first passing through Pass 1 10, then Pass 2 15, and then Pass 3 18. It is anticipated that additional passes can be incorporated into the non-linear solar receiver, preferably with each pass occurring at a significant inflection point in fluid heat transfer rates due to changes in thermal conductivity and density occurring as temperature increases. FIG. 13 also depicts the placement of the relatively cooler region within the non-linear solar receiver advantageously where less secondary reflections of emitted energy will occur, and the overlapping thermal communication of Pass 2 15 and Pass 3 18 as a means of obtaining a more even thermal flux into the heat transfer/working fluid to more closely match the solar flux along the length of the non-linear solar receiver. One exemplary is the design of the multi pass heat exchangers with a specific mass flow rate of the heat transfer/working fluid such that the heat transfer rate into the heat transfer/working fluid is within 25% of the solar flux rate across the surface of the non-linear solar receiver. The preferred embodiment has the heat transfer rate within 10% of the solar flux rate, and the particularly preferred embodiment has the heat transfer rate within 5% of the solar flux rate. Another anticipated benefit of the multi pass non-linear solar receiver is the utilization of an odd number of passes to enable the fluid inlet and discharge to take place on the same side enabling a reduction in distinct fluid joints, preferably concentric joints where the colder inlet temperature effectively insulates the relatively hotter discharge fluid. Yet another benefit of the non-linear solar receiver is the shape of the solar receiver designed to enable the approximately matching heat transfer rate and solar flux resulting from the solar collector/concentrator design. The solar collector/concentrator design, which can be any desired shape, is anticipated to deviate from the traditional parabolic trough to reduce wind load forces, thus reducing structural requirements and associated costs. Another exemplary solar collector/concentrator design is utilized with solar central tower receivers. Most notably, the solar central tower receivers are effectively gathering solar energy as very large linear Fresnel collector. The non-linear solar receiver having an approximately equal heat transfer rate and solar flux across the entire length of the solar receiver increases the effectiveness of the solar system.

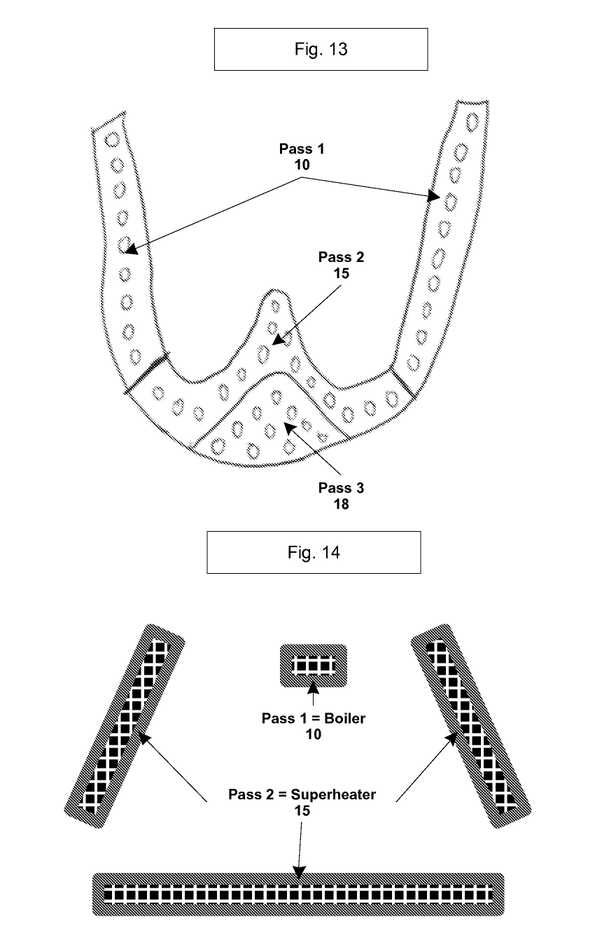

Turning to FIG. 14, FIG. 14 depicts a cross section of another embodiment of the non-linear solar receiver. This configuration is another exemplary of the shape of the non-linear receiver where Pass 1 10 effectively operates as the boiler of the heat transfer/working fluid, and Pass 2 15 effectively operates as the superheater of the heat transfer/working fluid. One exemplary has the required solar flux hitting the surface of Pass 1 10 directly from a solar collector/concentrator (not depicted, but known in the art), which being the lower temperature portion of the non-linear solar receiver will have a lower emissivity. Another portion of the reflected solar flux from the solar collector/concentrator will intentionally miss the Pass 1 10 region, which enables the solar collector/concentrator to be designed with a higher optical error as a means to reduce the solar collector/concentrator capital costs particularly under high load conditions. A further benefit of this configuration is that higher temperature of Pass 2 15 is within the region that enables at least a secondary reflection of emitted energy to be absorbed by another portion of the non-linear solar receiver.

Turning to FIG. 15, FIG. 15 depicts a cross section of yet another embodiment of another multi pass non-linear solar receiver. FIG. 15 is again where Pass 1 10 effectively operates as the boiler of the heat transfer/working fluid, and Pass 2 15 effectively operates as the superheater of the heat transfer/working fluid. This embodiment utilizes a hybrid design where the non-linear receiver is of approximately a spiral shape, thus the non-linear solar receiver operates as both a solar receiver and a secondary solar concentrator. The emissivity losses are minimized by the placement of the boiler closer to the sun facing portion of the non-linear solar receiver.

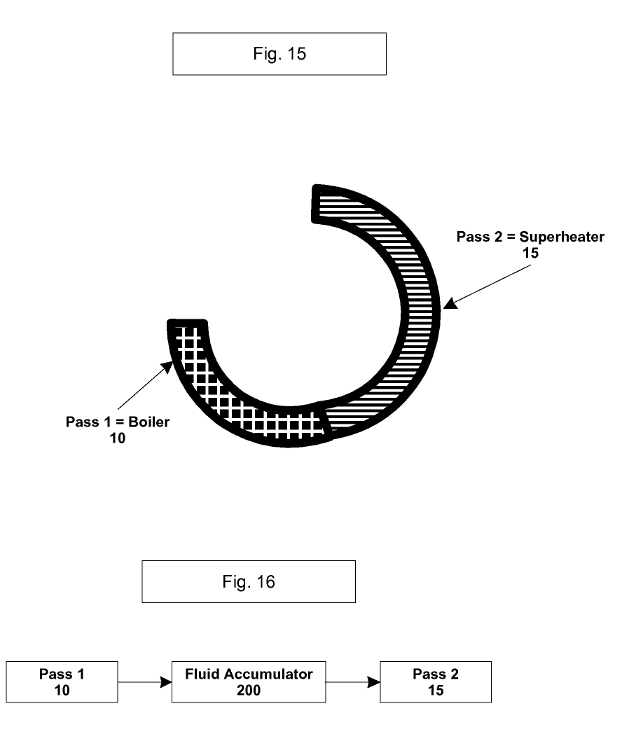

Turning to FIG. 16, FIG. 16 depicts a cross section of another embodiment of a multi pass non-linear solar receiver further comprised of a working Fluid Accumulator 200. One exemplary is the working Fluid Accumulator 200 placed in between the boiler and superheater external of the non-linear solar receiver. Pass 1 10 effectively operates as the boiler of the heat transfer/working fluid, and Pass 2 15 effectively operates as the superheater of the heat transfer/working fluid. The number of Fluid Accumulators 200 and their location between passes of solar receivers is anticipated to be flexible. FIG. 21 details another embodiment depicting Fluid Accumulator location.

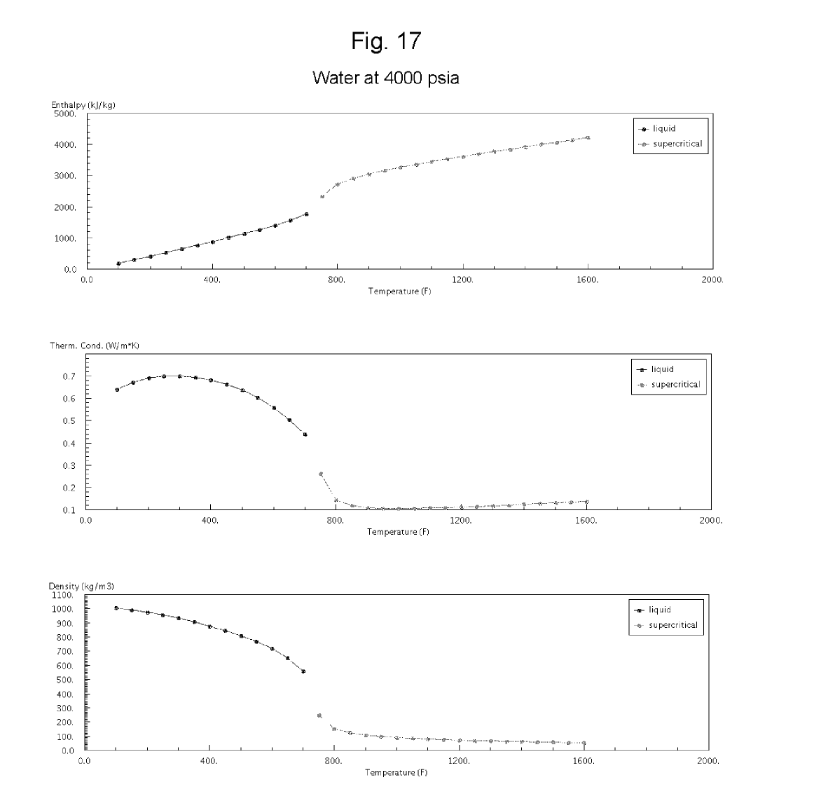

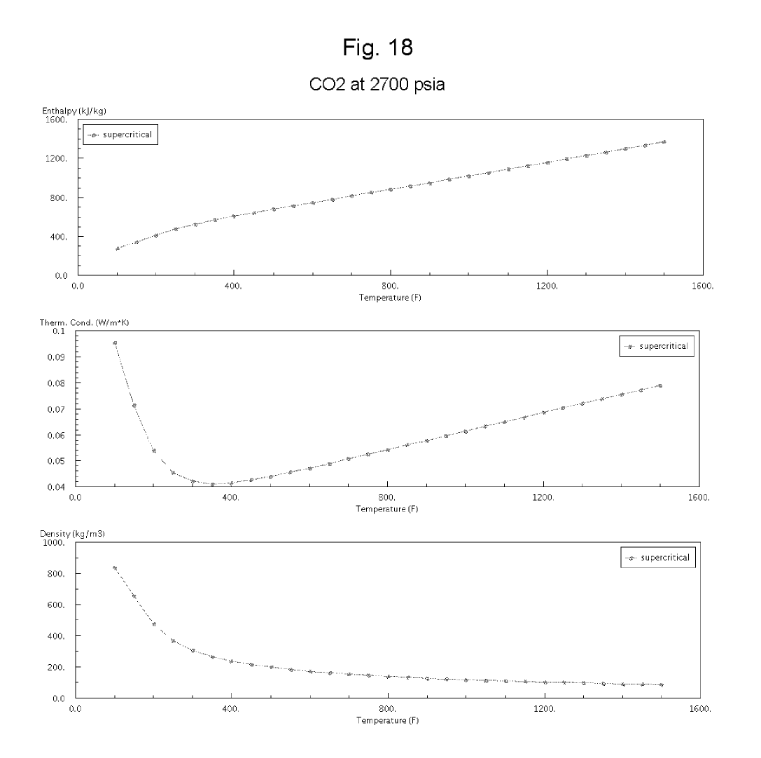

Turning to FIGS. 17 and 18, FIGS. 17 and 18 depict enthalpy, thermal conductivity, and density as a function of temperature for water at 4000 psia and carbon dioxide at 2700 psia respectively. The X,Y plot depicts mathematical inflection points, and also discontinuities (within FIG. 17) as known in the art. Additionally, regions of approximate linear relationships for the X, Y terms. The heat transfer rate is a function of all three functions shown which will create a fourth function also having mathematical inflection points, and discontinuities. The goal of the solar receiver design is to approximately reach equilibrium between solar flux on the solar receiver and heat transfer into the working fluid within the solar receiver, with a significant reduction in hot spots.

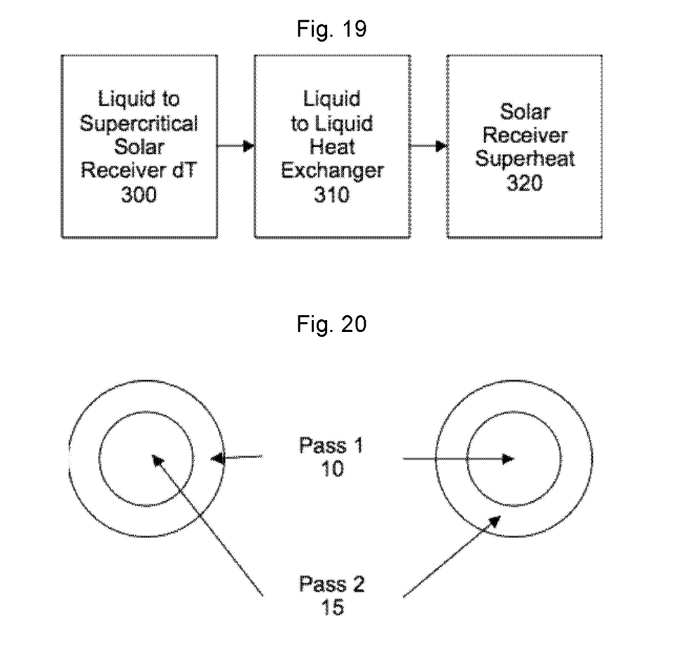

Turning to FIG. 19, FIG. 19 depicts a series of sequential solar receivers, where a working fluid is in thermal communication with a first solar receiver is Liquid to Supercritical Solar Receiver dT 300, then passes through a Liquid to Liquid Heat Exchanger 310, and then passes through at least a second Solar Receiver Superheat 320. The Liquid to Supercritical Solar Receiver dT 300 heats the working fluid to a temperature less than the supercritical temperature of the working fluid by a variable determined “dT” (supercritical temperature−dT) by user such that supercritical temperature−dT avoids the most significant change in linearity of heat transfer and/or the discontinuity of heat transfer. The preferred dT is dT.sub.a is selected such that linearity change is less than 25%, the preferred linearity change is less than 15%, and the particularly preferred linearity change is less than 5% of the respective slopes. The Liquid to Liquid Heat Exchanger 310 is designed to heat the working fluid from supercritical temperature−dT.sub.a up to a temperature of supercritical temperature+dT.sub.b, which is effectively through the region having a significant inflection point and/or discontinuity. The terms “liquid to liquid” is solely an expression of relative density, as the working fluid is either entirely already supercritical, is a liquid, or is in fact transitioning from subcritical to supercritical temperatures. The heat transfer fluid can be at any phase state, though the preferred is such that the heat transfer fluid does not have a phase change within the Liquid to Liquid Heat Exchanger 310. The heat transfer fluid can be a high density fluid such as a Therminol TM, a heat transfer fluid such as carbon dioxide at an operating pressure greater than 2700 psia, preferably at an operating pressure greater than 3500 psia, and particularly preferable at an operating pressure greater than 4000 psia. Alternatively, the heat transfer fluid can be water at an operating pressure greater than 5000 psia, preferably at an operating pressure greater than 6000 psia, and particularly preferable at an operating pressure greater than 6500 psia. The heat transfer fluid can also be air, where in fact the Liquid to Liquid Heat Exchanger 310 is effectively a Air to Liquid Heat Exchanger but is referenced in the figure as a direct substitution for 310. The working fluid then passes into the Solar Receiver Superheat 320 to further elevate the working fluid temperature. The Solar Receiver Superheat 320 can effectively be the second or third pass of a non-linear solar receiver, while the Liquid to Supercritical Solar Receiver dT 300 can effectively be the first pass of a non-linear solar receiver with the Liquid to Liquid Heat Exchanger 310 being between the passes.

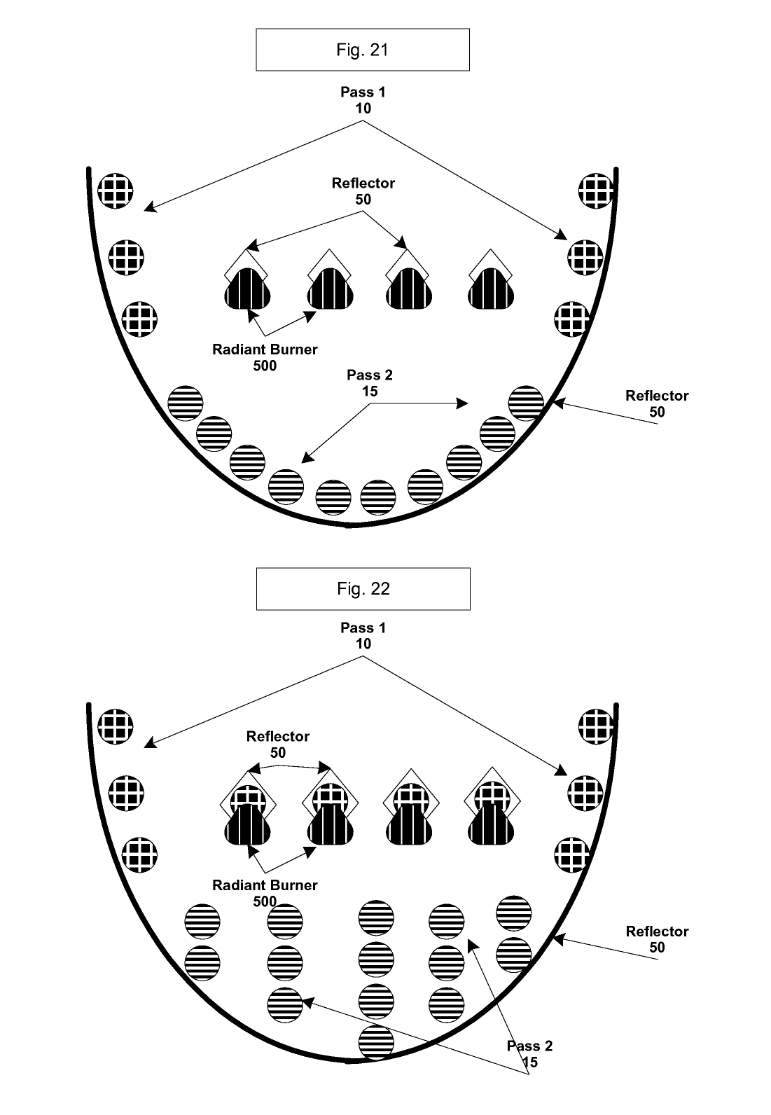

Turning to FIG. 20, FIG. 20 depicts two different configurations of a multi-pass non-linear solar receiver comprised of a “Pass 1” 10 microchannel heat exchanger and a “Pass 2” 15 microchannel heat exchanger. Both “Pass 1” 10 and “Pass 2” 15 are depicted as microchannel heat exchangers, but it is understand that either or both can also be standard heat exchangers with the key feature being concentric circles. It is further understood that the shapes can be designed to be any shape with the key feature being relative concentricity to each other. In one configuration “Pass 1” 10 is internal to “Pass 2” 15 such that the working fluid will take advantage of the higher surface area of “Pass 2” 15 relative to “Pass 1” 10. In the other configuration Pass 1” 10 is external to “Pass 2” 15 such that the working fluid will effectively insulate “Pass 2” 15 from the relatively lower ambient temperatures.

Turning to FIG. 21, FIG. 21 depicts an embodiment of the non-linear solar receiver such that the receiver captures radiant energy from both the sun and from a radiant burner 500. The non-linear receiver is comprised of a “Pass 1” 10 microchannel heat exchanger and a “Pass 2” 15 microchannel heat exchanger, though the combination of a radiant burner 500 and at least one of the “Pass 1” 10 microchannel heat exchanger and a “Pass 2” 15 microchannel heat exchangers is anticipated in addition to either or both of the “Pass 1” 10 heat exchanger and “Pass 2” 15 heat exchanger can be of any type of heat exchanger including circular tubes, diffusion bonded tubes of any shape, or other shape as known in the art of steam boilers or supercritical CO2 boilers. The “Pass 2” 15 heat exchangers are preferentially in the inner more portion of the non-linear solar receiver (including any shape of solar receiver as known in the art, particularly for solar tower receivers) to reduce emissivity losses. The placement of the radiant burner 500, and the optional use of internal reflectors 50 to maximize radiant energy from the radiant burner hitting the “Pass 2” 15 heat exchangers and furthermore to reflect solar radiant energy further into the non-linear solar receiver, are to maximize radiant energy into the non-linear solar receiver and minimize emissivity losses from the non-linear solar receiver. In this embodiment, the “Pass 2” 15 heat exchangers are lining the most internal portion of the non-linear solar receiver cavity.

Turning to FIG. 22, FIG. 22 is identical to FIG. 21 with the exception of the addition of “Pass 1” 10 heat exchangers operable to reduce emissivity of reflectors 50 in addition to providing cooling of the reflector 50 itself further enabling a material composition selection to both maximize reflectivity of the radiant energy from either/both the sun and the radiant burner 500 as well as material selection to control emissivity (particularly emissivity losses that will leave the non-linear solar receiver). The other exception as compared to FIG. 21 is the placement of the “Pass 2” 15 heat exchangers in rows perpendicular to the non-linear solar receiver entry portion of the radiant energy from the sun. It is understood that the placement of the “Pass 2” 15 heat exchangers, in addition any optional “Pass 1” 10 heat exchangers is optimized using optical methods as known in the art.

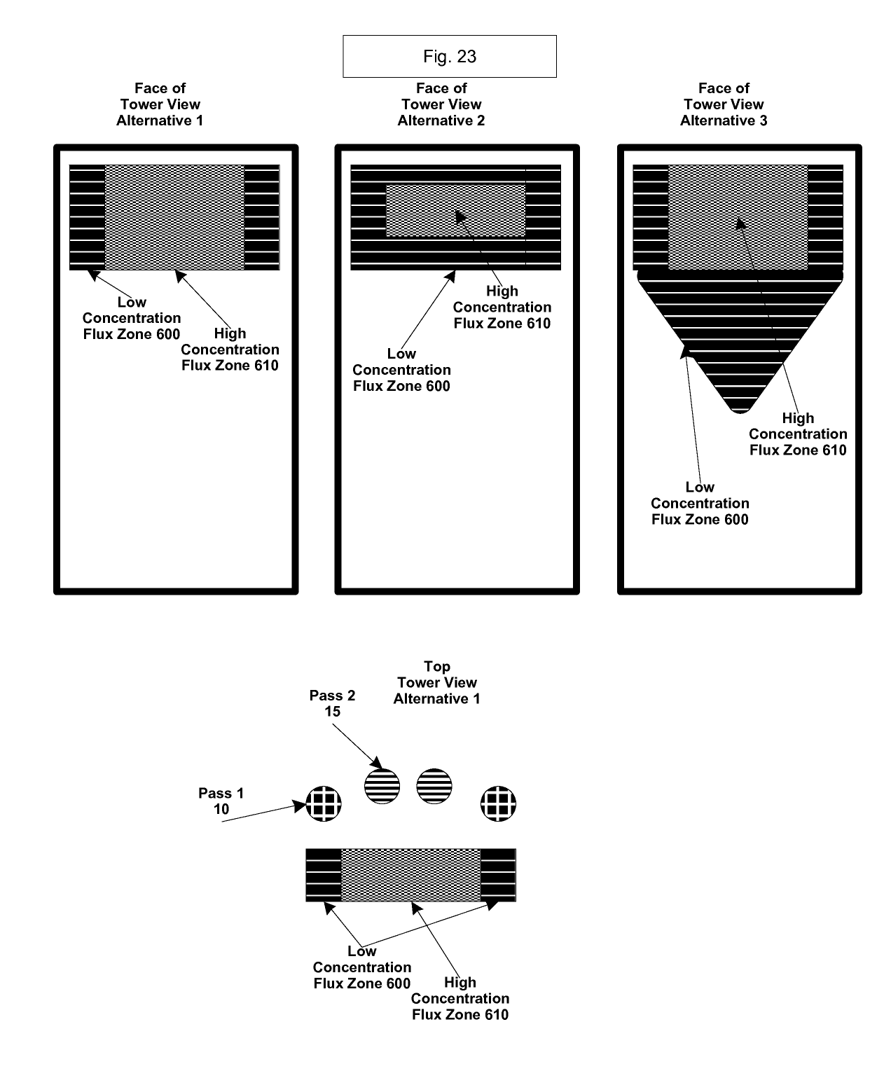

Turning to FIG. 23, FIG. 23 top tower view alternative depicts the placement of “Pass 1” 10 and “Pass 2” 15 heat exchangers relative to solar flux entering the non-linear solar receiver such that “Pass 1” 10 heat exchangers are preferentially located behind low concentration flux zone 600 and “Pass 2” 15 heat exchangers are preferentially located behind high concentration flux zone 610. FIG. 23 also depicts 3 face of tower view alternatives, where alternative 1 shows the low concentration flux zone 600 on the more exterior portion of the solar receiver relative to placement of the high concentration flux zone 610 in order to enable lower tracking accuracy reflectors (not depicted in the solar field as concentrators and as known in the art of solar tower configurations) and to enable stray radiant energy from the solar concentrators to be captured into the lower temperature portion of the heat exchangers to minimize emissivity losses. Alternative 2 is another embodiment of alternative 1 such that the entire high concentration flux zone 610 is surrounded at its exterior on all four sides. Alternative 3 further has an enlarged low concentration flux zone 600 with one anticipated embodiment being the solar concentrators within the solar field closest to the tower are focused on this relatively lower low concentration flux zone 600 (as compared to high concentration flux zone 610). The placement within alternative 3 anticipates that the closer solar concentrators have higher angles of incidence to the solar tower receiver leading to greater losses and less ability to be directed to the most innermost cavity portions of the non-linear solar receiver.

Although the invention has been described in detail with particular reference to certain embodiments detailed herein, other embodiments can achieve the same results. Variations and modifications of the present invention will be obvious to those skilled in the art and the present invention is intended to cover in the appended claims all such modifications and equivalents.

What is claimed is:

1. A non-linear solar receiver having at least two distinct heat exchanger circuits with the first heat exchanger of the at least two distinct heat exchangers having a fluid temperature within the first heat exchanger less than a second heat exchanger of the at least two distinct heat exchangers having a fluid temperature within the second heat exchanger.

2. The non-linear solar receiver according to claim 1 wherein the first heat exchanger is first to receive the incoming solar energy flux and the second heat exchanger is second to receive the incoming solar energy flux.

3. The non-linear solar receiver according to claim 2 wherein the first heat exchanger has the lowest emissivity surface within the receiver and the second heat exchanger has the highest effective absorption surface within the receiver.

4. The non-linear solar receiver according to claim 2 wherein the first heat exchanger is operable as a boiler and the second heat exchanger is operable as a superheater.

5. The non-linear solar receiver according to claim 1 further comprised of a photovoltaic cell and wherein the first heat exchanger is operable to provide active cooling of the photovoltaic cell.

6. The non-linear solar receiver according to claim 1 wherein the fluid is a supercritical fluid having a disassociation rate less than 0.5 percent at the temperature of the fluid temperature at the discharge of the second heat exchanger.

7. The non-linear solar receiver according to claim 6 further comprised of a thermodynamic cycle having a working fluid, wherein the fluid within at least one of the at least two distinct heat exchangers is identical to the working fluid of the thermodynamic cycle.

8. The non-linear solar receiver according to claim 7 further comprised of a control system operable to regulate the mass flow rate within the first heat exchanger and the second heat exchanger independently

9. The non-linear solar receiver according to claim 1 wherein emitted energy from either the first heat exchanger is reflected onto a portion of either the first heat exchanger having a lower fluid temperature or the second heat exchanger is reflected onto a portion of the first heat exchanger.

10. The non-linear solar receiver according to claim 1 further comprised of a solar concentrator to reflect the solar flux onto the non-linear solar receiver whereby the solar concentrator is asymmetric.

11. The non-linear solar receiver according to claim 1 having a heat transfer rate from the non-linear solar receiver to the fluid and having a solar flux rate, wherein the heat transfer rate is within 25 percent of the solar flux rate across the entire surface of the non-linear solar receiver.

12. The non-linear solar receiver according to claim 1 having a heat transfer rate from the non-linear solar receiver to the fluid and having a solar flux rate, wherein the heat transfer rate is within 10 percent of the solar flux rate across the entire surface of the non-linear solar receiver.

13. The non-linear solar receiver according to claim 1 having a heat transfer rate from the non-linear solar receiver to the fluid and having a solar flux rate, wherein the heat transfer rate is within 5 percent of the solar flux rate across the entire surface of the non-linear solar receiver.

14. The non-linear solar receiver according to claim 1 further comprised of a radiant burner operable to transfer radiant energy from the radiant burner and solar flux to the fluid on at least one heat exchanger of the at least two distinct heat exchangers.

15. The non-linear solar receiver according to claim 1 further comprised of a solar tower having the non-linear solar receiver having at least two distinct solar flux zones wherein the first heat exchanger is in proximity to a first lower flux zone of the at least two distinct solar flux zones and the second heat exchanger is in proximity to a second higher flux zone of the at least two distinct solar flux zones.
